(19) United States
(12) Patent Application Publication
(10) Pub. No.: US 2020/0008316 A1
(43) Pub. Date: Jan. 2, 2020

(54) FLEXIBLE AND CONFORMABLE HEAT SINKS AND METHODS OF MAKING AND USING THEREOF

(71) Applicant: Carbice Corporation, Atlanta, GA (US)

(72) Inventors: Baratunde Cola, Atlanta, GA (US); Craig Green, Atlanta, GA (US)

(21) Appl. No.: 16/021,562

(22) Filed: Jun. 28, 2018

(51) Int. Cl. H05K 7/20; H01L 23/373; H01L 21/48; F28F 21/06; F28F 3/02; F28F 3/04

(52) U.S. Cl. CPC H05K 7/2039; H01L 23/3737; H01L 23/3735; F28F 3/048; F28F 21/06; F28F 3/022; H01L 21/4871

(57) ABSTRACT

Heat sinks containing polymeric protrusions and single-layered or multilayered or multitiered CNT-based structures, and methods of making and using thereof are described herein.

### FIELD OF THE INVENTION

This invention is in the field of heat sinks which contain carbon nanotube arrays or sheets, particularly arrays or sheets which may be stacked to form multilayered or multitiered structures, as well as methods of making and using thereof.

### BACKGROUND OF THE INVENTION

Heat sinks are used to conduct thermal energy away from a heat-generating devices, such as computer chips. Heat sinks typically include aluminum or other metal extrusions as a common form of heat sink. These extrusions have a rigid base and extended surface area fins. Other versions of metal heat sinks are used and can include flexible copper foils in various shapes, which optionally may have electrically insulating coatings on one or both major surfaces.

Heat sink assemblies, however, suffer from several disadvantages when employing a rigid heat sink. They typically require the use of gap pads or gap fillers between the heat sink and the heat-generating device which result in poor thermal transfer uniformity, particularly where the group of devices to be cooled have a great degree of variance of height. Gap pads can suffer from varying degrees of thermal conductivity because the thermal conductivity through the thickness of gap pad is proportional to the amount of compression of the pad. In general, use of a gap pad can result in non-uniform thermal transfer causing overall inferior thermal conductivity.

For at least the foregoing reasons, there is a demand for heat sinks that are capable of dissipating heat from heat-generating devices that are not rigid and that can provide efficient heat dissipation without the need of a gap pad or gap filler.

Therefore, it is an object of the present invention to provide heat sinks which can be flexible and conformable and which can be applied onto a surface of a heat-generating device preferably without the need for a gap pad or gap filler.

### SUMMARY OF THE INVENTION

Heat sinks including a plurality of polymeric protrusions extending away from a base, each protrusion having a major dimension and a minor dimension, where the plurality of polymeric protrusions are contiguous with the base including a thermal interface material as described herein.

As shown in FIG. 1, a non-limiting schematic of a side-sectional view of a heat sink 100 according to an embodiment described includes a base 110 formed from or including a thermal interface material, as described herein, and having a plurality of polymeric protrusions 120 where polymeric protrusions 130 extend away from the base. The polymeric protrusions have major dimension 140 (i.e., height), a minor dimension 150 (i.e., width), and distance 160 between adjacent polymeric protrusions. In some instances, the minor dimension is tapered 170. In some instances, one or more additional layers (not shown) may be present below base 110. In some instances, components 110 and 120 are separate components which are brought together and are in direct and contiguous contact at an interface 125, which may include an optional layer (not shown) comprising an adhesive. In some instances, there is no distinct interface 125 between components 110 and 120.

The heat sinks can be conformable and flexible. For example, the heat sinks can conform to contact all of the desired surface of a heat generating device which is to be contacted, where the heat sink or substantially all of the surface desired and traps no or a minimum amount of air or voids and provides intimate contact between the surface interfaces contacted by the heat sink's base layer.

In certain instances, the heat sink is also reformable. A reformable heat sink can be heated and reformed into a new shape with a platen or die that is shaped to conform the heat sink to the heat-source device or substrate, such as a chip or other heat generating device. The heat sink article is reformable and can he customized to any desired shape.

In some instances, the heat sinks or components thereof (i.e., the base or thermal interface material therein) can absorb, reduce, or shield interference at electromagnetic and/or radio frequencies (EMI/RFI). In the case of the thermal interface material it is believed that the metal substrate and carbon nanotubes can absorb and scatter electromagnetic and/or radio frequencies.

The thermal contact resistance of the heat sinks described can be reduced by at least about 25%, 30%, 35%, 40%, 45%, 50%, 55%, 60%, 65%, 70% or greater when the base comprises a TIM as described herein, when measured, for example, using transient structure function analysis. In certain embodiments, the heat sinks exhibit thermal resistances of less than about 1.0, 0.9, 0.8, 0.7, 0.6, 0.5, 0.4, 0.3, 0.2, or 0.1 cm² K/W. In such embodiments, the thermal contact resistance is about 0.4, preferably about 0.3 cm² K/W. In certain embodiments, the heat sinks exhibit thermal resistances of between about 1 and 0.1 cm² K/W. In such embodiments, the thermal contact resistance is about 1, 0.9, 0.8, 0.7, 0.6, 0.5, 0.4, 0.3, 0.2, or 0.1 cm² K/W.

The heat sinks can be formed according to the methods detailed herein. In one non-limiting example, the method of preparing a heat sink includes the steps of:

(a) forming a base including a thermal interface material; and

(b) forming a plurality of polymeric protrusions on at least a surface of the base.

In another non-limiting example, the method of preparing a heat sink includes the steps of:

(a) forming a first base including a thermal interface material;

(b) forming a second base including a plurality of polymeric protrusions thereon; and

(c) attaching, adhering, or bonding the first and second bases such that the polymeric protrusions extend away from the first base.

The heat sinks formed according to the methods can have any suitable dimensions needed to cover one or more surfaces of a heat-generating device (such as a computer chip or component).

The heat sinks include a base having a single layered or single tiered or a multilayered or multitiered carbon nanotube-based thermal interface material (TIM). The heat sinks can be flexible and conformable. Such heat sinks are well suited for applications where the heat sink can conform to heat-generating devices or sources, such as computer chips, computer modules, multi-component system, electronic devices (i.e., displays), etc.

The heat sinks can be applied to node multi-chip modules (MCMs). The flexible and conformable heat sinks allow for uniform or essentially uniform contact with MCMs. The heat sinks are particularly suitable for such applications because they can be readily adjusted/reformed, if needed, to meet the tolerances required for such applications.

For some applications, the heat sinks can be used with personal computers and components thereof, server computers and components thereof, memory modules, graphics chips, radar and radio-frequency (RF) devices, disc drives, displays, including light-emitting diode (LED) displays, lighting systems, pipes, automotive control units, power-electronics, solar cells, batteries, communications equipment, such as cellular phones, thermoelectric generators, and imaging equipment, including MRIs. In certain instances, the heat sinks are contacted to a thermoelectric generator in contact with a waste heat source, as shown in FIGS. 3 and 4.

### BRIEF DESCRIPTION OF THE DRAWINGS

FIG. 1 shows a non-limiting schematic of a side-sectional view of a heat sink 100 including a base 110 formed from or including a thermal interface material, a plurality of polymeric protrusions 120 where the polymeric protrusions 130 extend away from the base. The polymeric protrusions have major dimension 140 (i.e., height), a minor dimension 150 (i.e., width), and distance 160 between adjacent polymeric protrusions. The minor dimension is optionally tapered 170 and an interface 125 may be present between the base and the plurality of polymeric protrusions.

FIG. 2A shows a non-limiting illustration of a thermal interface material (TIM), which may be a base or form part of a base, having a single tier, 200, with arrays or sheets of carbon nanotubes, 210, on each side of the substrate. FIG. 2B shows a non-limiting illustration of a thermal interface material (TIM), which may be a base or form part of a base, having three tiers, 200, with arrays or sheets of carbon nanotubes, 210, on each side of the substrates.

FIG. 3 is a non-limiting illustration of a heat sink (300) in contact with a thermoelectric generator (310) where the thermoelectric generator is in contact with a saddle (340), which may be made of a metal, and the saddle is wrapped around a pipe wall shown in cross-section (330) which is a waste heat source (320), such as from steam carried in the pipe. The saddle may optionally be held in place by some means, such as a bolt (350).

FIG. 4 is a non-limiting illustration of a flexible heat sink (400) in contact with a flexible thermoelectric generator (410) where the thermoelectric generator is wrapped around and in contact with a pipe wall shown in cross-section (430) which is a waste heat source (420), such as from steam carried in the pipe.

### DETAILED DESCRIPTION OF THE INVENTION

### I. Definitions

“Thermal Interface Material” (TIM), as used herein, refers to a material or combination of materials that provide high thermal conductance and mechanical compliance between a heat source and heat sink or spreader to effectively conduct heat away from a heat source.

“Conformable,” “Compliant,” or “Compliance,” as used herein, refers to the ability of a material to conform when contacted to one or more surfaces such that efficient conformance to the asperities, curvature, and/or nonplanarity of the adjoining surface results in sufficient or high contact areas at the interfaces between the surfaces and the material.

“Interdigitation” or “Interdigitating”, as used herein, refers to the ability and or degree which one or more individual nanostructure elements of an array or sheet to infiltrate or penetrate into the adjacent nanostructure elements of another array or sheet when the two different arrays or sheets are contacted or stacked.

“Carbon Nanotube Array” or “CNT array” or “CNT forest”, as used herein, refers to a plurality of carbon nanotubes which are vertically aligned on a surface of a material. Carbon nanotubes are said to be “vertically aligned” when they are substantially perpendicular to the surface on which they are supported or attached. Nanotubes are said to be substantially perpendicular when they are oriented on average within 30, 25, 20, 15, 10, or 5 degrees of the surface normal.

“Carbon Nanotube Sheet” or “CNT sheet”, as used herein, refers to a plurality of carbon nanotubes which are aligned in plane to create a free-standing sheet. Carbon nanotubes are said to be “aligned in plane” when they are substantially parallel to the surface of the sheet that they form. Nanotubes are said to be substantially parallel when they are oriented on average greater than 40, 50, 60, 70, 80, or 85 degrees from sheet surface normal.

“Coating material” as used herein, generally refers to polymers and/or molecules that can bond to CNTs through van der Waals bonds, π-π stacking, mechanical wrapping and/or covalent bonds and bond to metal, metal oxide, or semiconductor material surfaces through van der Waals bonds, π-π stacking, and/or covalent bonds.

“Elastic recovery” as used herein, refers to the ability of a material to return to its original shape following compression, expansion, stretching, or other deformation.

“Compression set” as used herein, refers to the permanent deformation of a material which remains when a force, such as compression, was applied to the material and the force was subsequently removed.

Numerical ranges disclosed in the present application include, but are not limited to, ranges of temperatures, ranges of pressures, ranges of molecular weights, ranges of integers, ranges of conductance and resistance values, ranges of times, and ranges of thicknesses. The disclosed ranges of any type, disclose individually each possible number that such a range could reasonably encompass, as well as any sub-ranges and combinations of sub-ranges encompassed therein. For example, disclosure of a pressure range is intended to disclose individually every possible pressure value that such a range could encompass, consistent with the disclosure herein.

Use of the term “about” is intended to describe values either above or below the stated value, which the term “about” modifies, in a range of approx. +/−10%; in other instances the values may range in value either above or below the stated value in a range of approx. +/−5%. When the term “about” is used before a range of numbers (i.e., about 1-5) or before a series of numbers (i.e., about 1, 2, 3, 4, etc.) it is intended to modify both ends of the range of numbers or each of the numbers in the series, unless specified otherwise.

### II. Heat Sinks

Heat sink article including a plurality of polymeric protrusions extending away from a base, where each protrusion having a major dimension and a minor dimension, and where the plurality of polymeric protrusions are contiguous with the base including a thermal interface material as described herein. The particular details of the polymeric protrusions and base formed from or containing a thermal interface material are found below.

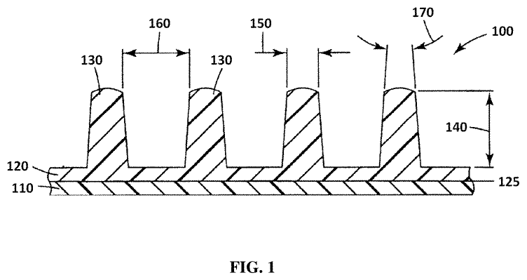

As shown in FIG. 1, a non-limiting schematic of a side-sectional view of a heat sink 100 according to an embodiment includes a base 110 formed from or including a thermal interface material, as described herein, and having a plurality of polymeric protrusions 120 where polymeric protrusions 130 extend away from the base. The polymeric protrusions have major dimension 140 (i.e., height), a minor dimension 150 (i.e., width), and distance 160 between adjacent polymeric protrusions. In some instances, the minor dimension is optionally tapered 170. In some instances, one or more additional layers (not shown) may be present below base 110. In some instances, components 110 and 120 are separate components which are brought together and are in direct and contiguous contact at an interface 125, which may include an optional layer (not shown) comprising an adhesive. In some instances, there is no distinct interface 125 between components 110 and 120.

The heat sinks can be conformable and flexible. The heat sink can conform to device dimensions, and elastically deform or deflect under installation force. The heat sink can conform to flat, non-flat, undulating, or other uniform or non-uniform surface shapes and provide a good thermal interface independent of the heat-generating device surface flatness. In most instances, the heat sinks conform to contact all of the desired surface of a device which is to be contacted with the heat sink or substantially all of the surface (i.e., at least about 90%, 91%, 92%, 93%, 94%, 95%, 96%, 97%, 98%, or 99%, or higher). In some instances, the heat sink can conform to contact multiple devices or components within the same substrate or system.

The heat sinks conform to contact all of the desired surface of a heat generating device which is to be contacted with the heat sink or substantially all of the surface desired and traps no or a minimum amount of air or voids and provides intimate contact between the surface interfaces contacted by the heat sink's base layer. Air in the interface between the heat sink and the device can increase thermal impedance. The flexible and conformable heat sink conforms to the heat-generating surface and minimizes gaps. The flexibility and surface conforming features of the heat sinks allow for the exclusion of components, such as pads, epoxies, greases, pastes, etc.) between the heat sink base and a heat-generating surface(s) of a device. Flexibility and conformability allow for the heat sink to be flattened or smoothed, as needed, to mate well or completely to the surface(s) of a heat-generating device.

The heat sinks allow for a bending to a radius of less than about 30 cm, less than about 10 cm, less than about 5 cm, or even lower) at room temperature without significantly adversely affecting the function or efficiency of the heat sink. That is, the heat sink does not crack, kink, or significantly plastically deform to a shape that may leave a gap between the heat sink and a heat-generating device or substrate thereof, whereas traditional metal heat sinks will permanently bend or kink. The heat sink preferably has a low level of elastic recovery force such that the heat sink does not “spring back” once applied.

The flexibility of the polymeric protrusions and the base of the flexible and conformable heat sink allow bending or flexing, deflecting, and/or absorbing forces (e.g., impact force, shock force, vibration force with variable energy and duration). In sonic instances, the heat sink can act as a vibration damper or shock isolator to the heat generating device to which it is attached.

In certain instances, the heat sink is also reformable. A reformable heat sink can be heated and reformed into a new shape with a platen or die that is shaped to conform the heat sink to the heat-source device or substrate, such as a chip or other heat generating device. The heat sink article is reformable and can be customized to any desired shape. For example, computer chips can have bowed, uneven, or less than perfectly planar surfaces which are easily accommodated via reforming the base and/or layers thereof of the heat sink. Reforming is useful for heat-generating devices with large degrees of non-flatness or curvature.

In some instances, the heat sinks or components thereof (i.e., the base or thermal interface material therein) can absorb, reduce, or shield interference at electromagnetic and/or radio frequencies (EMI/RFI). In the case of the thermal interface material it is believed that the metal substrate and carbon nanotubes can absorb and scatter electromagnetic and/or radio frequencies.

The thermal contact resistance of the heat sinks is reduced by at least about 25%, 30%, 35%, 40%, 45%, 50%, 55%, 60%, 65%, 70% or greater when the base comprises a TIM as herein, when measured, for example, using transient structure function analysis. In certain embodiments, the heat sinks exhibit thermal resistances of less than about 1.0, 0.9, 0.8, 0.7, 0.6, 0.5, 0.4, 0.3, 0.2, or 0.1 cm² K/W. In such embodiments, the thermal contact resistance is about 0.4, preferably about 0.3 cm² K/W. In certain embodiments, the heat sinks exhibit thermal resistances of between about 1 and 0.1 cm² K/W. In such embodiments, the thermal contact resistance is about 1, 0.9, 0.8, 0.7, 0.6, 0.5, 0.4, 0.3, 0.2, or 0.1 cm² K/W.

A. Polymeric Protrusions

The polymeric protrusions which form part of the heat sink article are contiguous with the base formed from a thermal interface material. The base is formed to include a plurality of polymeric protrusions extending away from the base. The inclusion of a plurality of polymeric protrusions increases the heat transfer ability of the heat sink, as compared to a heat sink without polymeric protrusions. In some instances, the heat transfer is increased by about 10%, 20%, 30%, 40%, 50%, 60%, 70%, 80%, 100%, 200%, or greater, as compared to a heat sink not having polymeric protrusions thereon.

The polymeric protrusions may be arranged in a regular or an irregular array. The polymeric protrusions may each be independently vertical or substantially vertical posts, cones, or extended rows or rails, or combinations thereof (wherein substantially vertical means at least about 80°, 81°, 82°, 83°, 84°, 85°, 86°, 87°, 88°, or 89° normal to the base. The plurality of polymeric protrusions may each be of different or varying heights and/or shapes or may be of the same heights or shapes. Any known layout can be used for the polymeric protrusions, such as hexagonal or other polygonal shapes, diagonal, sinusoidal, rails/posts, and combinations thereof.

The polymeric protrusions can be made from any known suitable polymer, such as, but are not limited to melt processable or extrudable polymer(s). Suitable examples include but are not limited to thermoplastic polymers, elastomeric polymers, thermoset polymers, and thermoplastic elastomers. Two or more polymers may be used in combination, such as in layers and/or blends to form the polymeric protrusions. The thermoset polymers used to form the protrusions, for example, can be crosslinked via known means, such as chemical or thermal agents, catalysts, irradiation, heat, light, and combinations thereof. In some instances, the polymer(s) used to form the protrusions may be selected such that it has a glass transition temperature below about 25° C. in order for the polymer to not be completely hard and glassy at room temperature.

The polymeric protrusions may be formed from polymer(s) alone or may further contain one or more thermally conductive materials or fillers therein. Exemplary conductive materials or fillers include, but are not limited to carbon black, carbon nanotubes (including any combination of single-walled, double-walled, or multi-wailed carbon nanotubes), graphite, graphene, reduced graphene oxide, partially reduced graphene oxide, carbon fibers, carbon fibers coated with a metal or other conductive material such as nickel, ceramic fiber mesh, ceramics which includes for example: boron nitride, aluminum oxide, silicon carbide, aluminum nitride, aluminum trihydrate, magnesium hydroxide, metals such as aluminum, iron oxides, copper, stainless steel, etc., including metal foils. In some instances, the conductive materials or fillers are in the form of a plurality of particles where suitable particles can vary by size, type (such as crystal forms of hexagonal, rhombohedral, cubic, etc.), agglomerated particle size, aspect ratio, surface coatings that enhance surface physical properties of the particles, pH characteristics (e.g., acidic, basic, including Lewis acid or Lewis base particles), and particle blends. The particles may be spherical, non-spherical, or elongated particles and may be aligned along the major dimension of the polymeric protrusions. Higher aspect ratio particle shapes may also be used which include fibers, rods, needles, whiskers, ellipsoids, and flakes. The particles may be hollow, solid, or metal-coated particles. The size of the particles is selected to provide thermal conductivity, as well adequate distribution within the polymer (preferably uniform). In some cases, the particles have a major dimension of at least about 0.1 to 5 microns. The particles can have an aspect ratio greater than about 1 to 1 (major dimension to minor dimension), more preferably greater than about 1.25 or even 1.5 to 1. Elongated particles, for example, can have an aspect ratio greater than about 2 to 1, more preferably greater than about 5 to 1, 10 to 1, or even greater. In some instances, the conductive materials or fillers may be chosen in order to absorb or reduce interference at electromagnetic and/or radio frequencies (EMI/RFI). For example, particles of iron oxides and nickel-coated particles may be used for absorption or reduction of interference at electromagnetic and/or radio frequencies. In some instances, the low intrinsic electrical conductivity of the polymer protrusions may reduce the tendency of the heat sink to act as an antenna for unintended EM/RF transmission or absorption when compared to a similar structure composed of metallic protrusions.

The polymer(s) forming each of the polymeric protrusions of the heat sink may be the same, similar, or different. Typically, each of the polymeric protrusions of a heat sink are formed of the same or of substantially similar polymer compositions. “Substantially similar” means having a composition wherein at least about 85 weight percent (wt %), more preferably at least about 90 wt %, and in some embodiments at least about 95 wt %, of the substantially similar compositions are identical. In certain instances, each of the polymeric protrusions of a heat sink are formed from dissimilar polymer compositions where “dissimilar” means that the compositions can vary by more than about 15 wt %.

The polymeric protrusions generally have parallel sidewalls (e.g., cylindrical), may be tapered, or may be a combination thereof, which facilitates removal from a mold used in their manufacture. The polymeric protrusions have a major dimension (height) and minor dimension (width) and distance between adjacent polymeric protrusions. In some instances, any suitable two-dimensional shape can be used for the polymeric protrusions, such as straight and/or curved sidewalls resulting in rectangular, triangular, trapezoidal, hemispherical, or other profiles. The shapes of the polymeric protrusions present on a heat sink may be the uniform or a combination of those mentioned, optionally with undercut(s) features. In another instance, any desired three-dimensional shape can be used for the polymeric protrusions, such as cylinder, cone, truncated cone, pyramid, truncated pyramid, hemisphere, truncated hemisphere, rectangle, square, hexagon, octagon, other polygonal shape, additional suitable shapes, and combinations of the aforementioned shapes resulting in hybrid shapes. One or more shapes can be present in the plurality of polymeric protrusions of the heat sink.

Shape selection for the polymeric protrusions can be made to modify or control certain parameters including, but not limited to, surface area, airflow around the shape(s), flexibility, and conductivity, etc. The shape(s) may have tapered widths. The polymeric protrusions protrusion may terminate in any shape, such as being flat, round, wave, or an irregular shape. The polymeric protrusions may have the same (uniform), similar, or different heights. The sides of the polymeric protrusions can have any shape compatible with the protrusion shape such as flat, convex, concave, or irregular shape. In some cases, the polymeric protrusions may include posts with an expanded surface area top portion which is wider, such as at least 10% wider or 15% wider than the thinnest section of the polymeric protrusions. The top portion of each of the polymeric protrusions can be of any known shape, such as a mushroom, a point, a bulb, airfoil, independently with a convex or concave surface in addition to its overall shape, and the top portion may be symmetrical or asymmetrical.

The polymeric protrusions can assist and/or direct the flow of a cooling medium (such as air, water, or other cooling fluid) to increase the heat transfer efficiency of the heat sink. The polymeric protrusions can be selected to afford higher overall flow of the cooling medium to improve overall heat transfer and heat sink performance In some instances, the polymeric protrusions can include additional features such as being fluted, dimpled, recessed, and/or ribbed. These features can be designed to modify cooling medium flow around the protrusions which can also increase the heat transfer surface area for a given polymeric protrusion type present in the heat sink.

The polymeric protrusions can be flexible or inflexible. Flexible means that the polymeric protrusions are capable of being deflected by at least about 50% of the thickness (at the thinnest region) of the polymeric protrusions away from a center line of the protrusions without breaking, cracking, or plastically deforming, when the deflection occurs at the thinnest area of the protrusion.

The polymeric protrusions can be of any suitable size useful for dissipating heat from a heat-generating surface. Generally a minimum height is at least about 0.5 mm, about 0.6 mm, about 0.7 mm, about 0.8 mm, about 0.9 mm, about 1 mm, or greater. The maximum height is generally below about 30 mm, below about 20 mm, or below 15 mm. Polymeric protrusion dimensions and spacing are preferably selected for optimal heat transfer, with increasing surface area generally increasing heat flow until a maximum is reached. Similarly, more polymeric protrusions per unit base area generally increases heat flow until a maximum is reached. Generally the distance between polymeric protrusions is chosen to be at least about 0.5 mm, or at least about 1 mm considering factors for ensuring maximizing flow of a cooling medium.

In some instances, the polymeric protrusions extend above the base at least one-half the thickness of the base. The ratio of base thickness to protrusion height can be selected to be at least 0.5:1, at least 1:1, at least 1:2, at least 1:3, at least 1:6, or at least 1:8.

The primary direction of heat flow is associated with the major dimension of the polymeric protrusions of the heat sink. In some cases, the thermal conductivity of the protrusion in a direction of heat flow is at least about 5% greater, at least about 10%, or greater, than the thermal conductivity in a direction normal to the preferred direction. In other cases, the thermal conductivity in a direction of heat flow is a factor of about 1.5 to about 5 greater, or higher, than the thermal conductivity in a direction normal to the preferred direction.

The Young's modulus of the polymeric protrusions when measured at 70° F. is typically less than 1,000,000 psi, less than 40,000 psi, or less than 15,000 psi. For comparison, the modulus of aluminum is approximately 10,000,000 psi.

B. Base

The base is formed of or includes a thermal interface material (TIM), as described below, and forms part of the heat sinks described in detail above.

The base may include one or more features selected to modify the flexibility of the base. For example, indentations, slits, channels, cut-outs, notches, holes, through holes, hinges, areas of differing thickness, or any combination thereof can be used to increase the flexibility of the base. Base flexibility can be varied by direction and based on design selection. For example, the flexibility can be higher in one direction.

The base may have a uniform thickness or a non-uniform thickness. For example, a thinner base region may be used to form contiguous contact with a lower-power region of a heat generating device and a thicker base region may be used to form contiguous contact with a higher-power region of a heat generating device, such as a computer chip.

The base is conformable and adaptable to contact a shaped surface. The base may include one or more cavities adapted to accept at least a portion of a heat-generating device or part thereof. The base can extend beyond the top surface of a heat-generating device, and optionally may be of a suitable size to cover at least a portion of one or more sides of the heat-generating device. The base can be corrugated or include a corrugated layer therein. The base can include a textured or contoured surface, such as to accommodate a selectively non-uniform surface. The stiffness of the base can be below about 100,000 N/m, below about 50,000, 40,000 30,000, or below about 20,000 N/m. In some instances, the stiffness of the base is below about 10,000 N/m, below about 5, 4, 3, 2, 1, or 0.5 N/m.

The base may be formed of only from a thermal interface material (TIM) described below or may additionally include one or more optional additional layer(s) therein. Additional optional layer(s) which may form part of the base, in addition to the thermal interface material forming the base include, for example, a backing layer which can provide further functionality, such as to stabilize and/or reinforce the heat sink, provide resistance to stretching, and/or improve tear resistance, as well as a variety of other functions. A backing layer can, for example, be an adhesive layer used for attaching the heat sink to a surface of a heat-generating device. Additional optional layers, in addition to the backing layer, can also include an adhesive layer, a reinforcing layer, a heat spreading layer, or a combination thereof. When the attachment is an adhesive bond a release liner can also be included with the base. In certain instances where the base is formed from a thermal interface material, the TIM itself may be adhesive (as detailed below).

In some instances, the base can include a layer(s) selected to improve one or more properties such as conductivity and/or mechanical strength. This layer may include thermally conductive polymers, fillers, nickel or nickel-coated scrims, carbon scrims, graphite, nickel-coated carbon scrims, combinations thereof, and/or blended materials, oriented wires, random wire mesh (such as steel wool), non-woven mesh (ceramic, metal, etc.) or foil (aluminum, copper, etc.). Scrim can be internal, external, or partially embedded in the base of some higher thermal conductivity material(s) to the base without significantly impacting the flexibility of the heat sink and improves the heat spreading performance of the heat sink.

In instances where the base includes an optional adhesive layer, typically the adhesive material of the layer is selected to provide a bond to a heat generating device or a substrate upon which a heat-generating device is mounted. Any known adhesive type can be used, such as pressure sensitive, thermosetting, thermoplastic, hot melt, or other thermal bond film, radiation-cured or curable, solvent-activatable or solvent-activated, low surface energy adhesive, and combinations thereof. Exemplary adhesives include epoxy adhesive and adhesive such as acrylate, silicone, polyester, and/or polyolefin adhesive(s), silicone and acrylate adhesives, combinations thereof and may also include appropriate known curing agents. The adhesive of the optional layer may be a uniform layer(s) or be formed of stripes or islands of adhesive(s). Any known adhesive chemistry can be used, such as epoxy, urethane, synthetic rubber, natural rubber, polyolefin, silicone, ionomer, cyanate ester, acrylic and combinations, intermittent regions, or layers thereof. The adhesive may include one or more known additives, usually included for a particular purpose such as reinforcing filaments, and thermally conductive particles. Examples of additives include flame-retardants, plasticizers, tackifiers, processing aids, antistatic agents, and oils. Useful flame-retardant additives include halogenated and non-halogenated organic compounds, organic phosphorus-containing compounds (such as organic phosphates), inorganic compounds, and inherently flame-retardant polymers. These additives are added to or incorporated into the adhesive.

The adhesive may contain thermally conductive particles that can improve thermal conductivity in the path between the heat-source substrate (i.e., heat generating device) and the heat sink article. Generally, increasing the size of these particles to the same adhesive thickness will increase the thermal conductivity between a heat generating device/substrate and the heat sink. Particle sizes can have a major dimension of at least about 1-2 μm and about 30 μm or below or between about 5 and 20 μm. Combinations of different particle size materials can also be used. Generally, larger particles are used to increase bulk thermal conductivity. The minor dimension of the particles is about the same (for generally spherical particles) or less than the major dimension (for acicular particles, fibers, plates, etc.).

The base including an adhesive layer or a formed of an adhesive TIM may releasably bond or permanently bond the base of the heat sink to a surface of a device(s). Releasably bonding adhesives include, for example, materials that are reworkable, heat-releasable, stretch-releasable, solvent-releasable, and the like.

### 1. Thermal Interface Materials

The TIMs forming or present in the base are formed from carbon nanotube arrays or carbon nanotube sheets supported on, or attached to, the surface of an inert substrate/support, as described below. In some embodiments, the TIMs are formed of a single-tiered or single layered carbon nanotube array or carbon nanotube sheet. In certain other embodiments, the carbon nanotube arrays or sheets described below can be stacked according to the methods to afford multilayered or multitiered structures, as described in further detail below.

### a. Carbon Nanotube Arrays

Carbon nanotube arrays contain a plurality of carbon nanotubes supported on, or attached to, the surface of an inert substrate/support, such as a metallic (e.g., Al or Au) foil, metal alloys (i.e., steel). In some embodiments, the substrate/support can be a flexible, electrically, and thermally conductive substrate, such as graphite or other carbon-based material. In yet other embodiments, the substrate/support can be an electrically insulating substrate such as a flexible ceramic. The CNT arrays can be formed using the methods described below. The CNTs are vertically aligned on the substrate/support. CNTs are said to be “vertically aligned” when they are substantially perpendicular to the surface on which they are supported or attached. Nanotubes are said to be substantially perpendicular when they are oriented on average within 30, 25, 20, 15, 10, or 5 degrees of the surface normal.

Generally, the nanotubes are present at a sufficient density such that the nanotubes are self-supporting and adopt a substantially perpendicular orientation to the surface of the multilayer substrate. Preferably, the nanotubes are spaced at optimal distances from one another and are of uniform height to minimize thermal transfer losses, thereby maximizing their collective thermal diffusivity.

The CNT arrays contain nanotubes which are continuous from the top of the array (i.e., the surface formed by the distal end of the carbon nanotubes when vertically aligned on the multilayer substrate) to bottom of the array (i.e., the surface of the multilayer substrate). The array may be formed from multi-wall carbon nanotubes (MWNTs), which generally refers to nanotubes having between approximately 4 and approximately 10 walls. The array may also be formed from few-wall nanotubes (FWNTs), which generally refer to nanotubes containing approximately 1-3 walls. FWNTs include single-wall carbon nanotubes (SWNTs), double-wall carbon nanotubes (DWNTS), and triple-wall carbon nanotubes (TWNTs). In certain embodiments, the nanotubes are MWNTs. In some embodiments, the diameter of MWNTs in the arrays ranges from 10 to 40 nm, more preferably 15 to 30 nm, most preferably about 20 nm. The length of CNTs in the arrays can range from 1 to 5,000 micrometers, preferably 5 to 5000 micrometers, preferably 5 to 2500 micrometers, more preferably 5 to 2000 micrometers, more preferably 5 to 1000 micrometers. In some embodiments, the length of CNTs in the arrays can range from 1-500 micrometers, even more preferably 1-100 micrometers.

The CNTs display strong adhesion to the multilayer substrate. In certain embodiments, the CNT array or sheet will remain substantially intact after being immersed in a solvent, such as ethanol, and sonicated for a period of at least five minutes. In particular embodiments, at least about 90%, 95%, 96%, 97%, 98%, 99%, or 99.9% of the CNTs remain on the surface after sonication in ethanol.

### b. Carbon Nanotube Sheets

Carbon nanotube sheets are also described herein. The sheets contain a plurality of carbon nanotubes that support each other through strong van der Waals force interactions and mechanical entanglement to form a freestanding material. The CNT sheets can be formed using the methods described below. The CNTs form a freestanding sheet and are aligned in plane with the surface of this sheet. CNTs are said to be “aligned in plane” when they are substantially parallel to the surface of the sheet that they form. Nanotubes are said to be substantially parallel when they are oriented on average greater than 40, 50, 60, 70, 80, or 85 degrees from sheet surface normal.

Generally, the nanotubes are present at a sufficient density such that the nanotubes are self-supporting and adopt a substantially parallel orientation to the surface of the sheet. Preferably, the nanotubes are spaced at optimal distances from one another and are of uniform length to minimize thermal transfer losses, thereby maximizing their collective thermal diffusivity.

The CNT sheets may be formed from multi-wall carbon nanotubes (MWNTs), which generally refers to nanotubes having between approximately 4 and approximately 10 walls. The sheets may also be formed from few-wall nanotubes (FWNTs), which generally refers to nanotubes containing approximately 1-3 walls. FWNTs include single-wall carbon nanotubes (SWNTs), double-wall carbon nanotubes (DWNTS), and triple-wall carbon nanotubes (TWNTs). In certain embodiments, the nanotubes are MWNTs. In some embodiments, the diameter of MWNTs in the arrays ranges from 10 to 40 nm, more preferably 15 to 30 nm, most preferably about 20 nm. The length of CNTs in the sheets can range from 1 to 5,000 micrometers, preferably 100 to 5000 micrometers, preferably 500 to 5000 micrometers, more preferably 1000 to 5000 micrometers. In some embodiments, the length of CNTs in the sheets can range from 1-500 micrometers, even more preferably 1-100 micrometers.

### 2. Coating(s)/Coating Materials

The CNT array or sheet can include a coating or coating material (terms can be used interchangeably) which adheres or is bonded to the CNTs. The coating/coating material can be applied as described below. In some embodiments, the coating contains one or more oligomeric materials, polymeric materials, waxes, or combinations thereof. In other embodiments, the coating contains one or more non-polymeric materials. In some embodiments, the coating can contain a mixture of oligomeric, waxes, and/or polymeric material and non-polymeric materials.

In certain embodiments, the coating material(s) act as a bonding agent(s) which can bonded, such as chemically, the carbon nanotubes of the stacked arrays or sheets. Without limitation, such coating material(s) which can act as bonding agents(s) can be selected from adhesives (i.e., acrylate adhesives) and a phase change material (i.e., a wax or waxes).

In some embodiments, the coating which adheres or is bonded to the CNTs of an array is applied before two or more CNT arrays or sheets are stacked while in other embodiments, the coating which adheres or is bonded to the CNTs of an array is applied following stacking of two or more CNT arrays or sheets. In yet other embodiments, the coating is infiltrated or backfilled into multilayered or multitiered structures formed of stacked CNT arrays or sheets and adheres or is bonded to the CNTs of the arrays forming the structure. As used herein, “infiltration” or “infiltrated” refer to a coating material(s) which are permeated through at least some of the carbon nanotubes of the arrays or sheets which were stacked to form the multilayered or multitiered structures. In some embodiments, the extent of infiltration is in the range of 0.1-99.9%. In some embodiments, the infiltrated coating material at least partially fills the interstitial space between carbon nanotubes while in some other embodiments the infiltrated coating coats at least some of the surfaces of the carbon nanotubes, or both. In some embodiments, the infiltrated coating material fills the all or substantially all (i.e., at least about 95%, 96%, 97%, 98%, or 99%) of the interstitial space between carbon nanotubes present in the tiers or layers of the structure formed by stacking of the CNT arrays or sheets.

A variety of materials can be coated onto the CNT arrays or sheets, prior to stacking, during stacking, or following stacking. In particular embodiments, the coatings can cause a decrease in the thermal resistance of the CNTs of arrays or sheets of structure having a plurality of layers or tiers, as defined herein. The coatings can be applied conformally to coat the tips and/or sidewalls of the CNTs. It is also desirable that the coating be reflowable as the interface is assembled using, for example, solvent, heat or some other easy to apply source. Polymers used as coatings must be thermally stable up to at least 130° C. In some embodiments, the coating is readily removable, such as by heat or dissolution in a solvent, to allow for “reworking” of the interface. “Reworking”, as used herein, refers to breaking the interface (i.e., removing the coating) by applying solvent or heat.

### a. Polymeric Coating Materials

In some embodiments, the coating is, or contains, one or more polymeric materials. The polymer coating can contain a conjugated polymer, such as an aromatic, heteroaromatic, or non-aromatic polymer, or a non-conjugated polymer.

Suitable classes of conjugated polymers include polyaromatic and polyheteroaromatics including, but not limited to, polythiophenes (including alkyl-substituted polythiophenes), polystyrenes, polypyrroles, polyacetylenes, polyanilines, polyfluorenes, polyphenylenes, polypyrenes, polyazulenes, polynaphthalenes, polycarbazoles, polyindoles, polyazepines, poly(3,4-ethylenedioxythiophenes), poly(p-phenyl sulfides), and poly(p-phenylene vinylene). Suitable non-aromatic, conjugated polymers include, but are not limited to, polyacetylenes and polydiacetylenes. The polymer classes listed above include substituted polymers, wherein the polymer backbone is substituted with one or more functional groups, such as alkyl groups. In some embodiments, the polymer is polystyrene (PS). In other embodiments, the polymer is poly(3-hexythiophene) (P3HT). In other embodiments, the polymer is poly(3,4-3thylenedioxythiophene) (PEDOT) or poly(3,4-3thylenedioxythiophene) poly(styrenesulfonate) (PEDOT:PSS). In other embodiments, the polymer is a non-conjugated polymer.

Suitable non-conjugated include, but are not limited to, polyvinyl alcohols (PVA), poly(methyl methacrylates) (PMMA), polydimethylsiloxanes (PDMS), polyurethane, silicones, acrylics, and combinations (blends) thereof.

In other embodiments, the polymer is a paraffin wax. In other embodiments, the polymer is a synthetic wax such as Fischer-Tropsch waxes or polyethylene waxes. In other embodiments, the polymer is a wax that has a melting temperature above 80, 90, 100, 110, or 120° C., preferably above 130° C.

In other embodiments, the polymer is an adhesive, such as, but not limited to, a hot glue or hot melt adhesive that combines wax, tackifiers and a polymer base to provide improved adhesion properties to one or more surfaces. In some embodiments, the adhesive is a pressure sensitive adhesive. In certain other embodiments, the adhesive is a monomer that polymerizes upon contact with air or water such as a cyanoacrylate. In yet other embodiments, the adhesive is a combination of a pressure sensitive adhesive and a thermally activated (or activatable) adhesive polymers which enhances ease of adhesion of a multilayered or multitiered structure described herein which includes such a combination of coatings to a surface(s), by way of the pressure sensitive adhesive and additional and more permanent or semi-permanent adhesion by way of the thermal adhesive. In yet some other embodiments, the adhesive includes a thermoset adhesive or a heat cure epoxy.

### 3. Other Coating Materials

### a. Metallic Nanoparticles

The CNT arrays or sheets can additionally be coated with one or more metal nanoparticles. One or more metal nanoparticles may be adsorbed to the distal ends and/or sidewalls of the CNTs to bond the distal ends and/or sidewalls of the CNTs to a surface, reduce thermal resistance between the CNT array or sheet and a surface, or combinations thereof. Metal nanoparticles can be applied to CNT arrays or sheets using a variety of methods known in the art.

Examples of suitable metal nanoparticles include palladium, gold, silver, titanium, iron, nickel, copper, and combinations thereof.

### b. Flowable or Phase Change Materials

In certain embodiments, flowable or phase change materials are applied to the CNT arrays or sheets prior to stacking, during stacking, or following stacking. Flowable or phase change materials may be added to the CNT array or sheet to displace the air between CNTs and improve contact between the distal ends and/or sidewalls of CNTs and a surface, and as a result reduce thermal resistance of the array or sheet and the contact between the array or sheet and a surface, or combinations thereof. Flowable or phase change materials can be applied to CNT arrays using a variety of methods known in the art.

Examples of suitable flowable or phase change materials include paraffin waxes, polyethylene waxes, hydrocarbon-based waxes in general, and blends thereof. Other examples of suitable flowable or phase change materials that are neither wax nor polymeric include liquid metals, oils, organic-inorganic and inorganic-inorganic eutectics, and blends thereof. In some embodiments, the coating material, such as a non-polymeric coating material and the flowable or phase change material are the same material or materials.

### 4. Multilayered or Multitiered Carbon Nanotube Structures

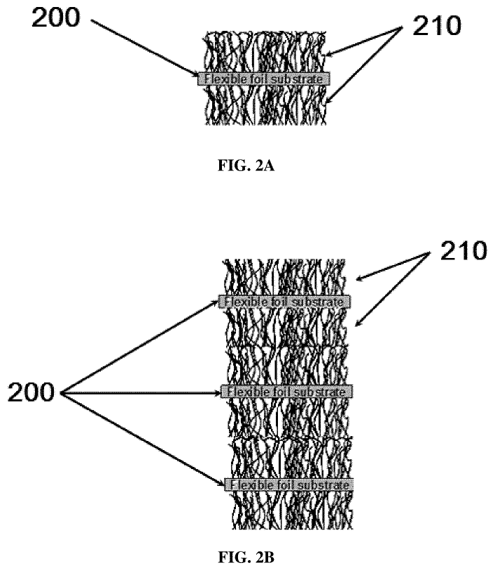

The CNT arrays or sheets described above can be stacked according to the methods described below to afford multilayered or multitiered structures. A non-limiting example of a three layered/tiered structure is shown in the schematic of FIG. 2B. A layer or tier is formed by contacting/stacking the carbon nanotubes of two CNT arrays or sheets, which interdigitate at least partially, and which may optionally be coated with a suitable coating material as described herein.

In some embodiments the multilayered or multitiered structures can further include a coating, a coating of metallic nanoparticles, and/or a coating of flowable or phase change materials on the nanostructure elements, such as CNTs, of the arrays.

At least two CNT arrays or sheets can be stacked to form the multilayered or multitiered structures. For example, FIG. 2B shows stacking of three CNT arrays (right side). By using more CNT arrays the thickness of the multilayered or multitiered structures can be increased as needed. In some embodiments, up to 5, 10, 15, 20, 25, 30, or more CNT arrays or sheets can be stacked according to the method described above. In some embodiments, multilayered or multitiered structures can include three, four, five, six, or seven layers or tiers as pan of the multilayered or multitiered structure. The thickness of the resulting multilayered or multitiered structures formed by stacking can be in the range 1-10,000 microns or more. In some embodiments, the thickness of the resulting multilayered or multitiered structures formed by stacking can be 1-3,000 micrometers, even more preferably 70-3,000 micrometers. In some embodiments, the number of layers and/or thickness is based on the thickness of the CNT forest formed on the arrays used in the stacking process.

In a non-limiting embodiment, at least two vertically aligned arrays or sheets formed on supports/substrates are stacked/contacted such that the nanostructure elements, such as CNTs, of the arrays at least partially interdigitate on contact. In one embodiment full interdigitation of nanostructure elements of the arrays occurs within one another when stacked. In other embodiments the arrays may interdigitate only at the tips of the nanostructure elements, such as CNTs. In yet other embodiments, the individual nanostructures can navigate through the nanostructures of the adjacent array during the interdigitating process and the nanostructure elements of the individual arrays, such as the CNTs or some portion thereof, fully or substantially interdigitate within one another; “substantially,” as used herein, refers to at least 95%, 96%, 97%, 98%, or 99% interdigitation between the nanostructure elements of the individual arrays. In some embodiments, the extent of interdigitation is in the range of about 0.1% to 99% or at least about 1%, 5%, 10%, 20%, 30%, 40%, 50%, 60%, 70%, 80%, 90%, or 95%.

In some embodiments the nanostructures of the stacked arrays, which interdigitate at least partially, may also form into larger superstructures, such as, but not limited to, tube bundles, clumps, or rows. These superstructures may be formed through mechanisms such as capillary clumping or by way of application of a polymer coating prior to, during, or following the stacking process.

In some embodiments, a polymer coating and/or adhesive, or other coating as described above, is applied to the CNT array(s) which are subsequently stacked. In such embodiments, the thickness of the coating and/or adhesive, or other coating as described above, is about 1-1000 nm, more preferable 1-500 nm, and most preferably 1-100 nm.

In addition to the above, the favorable deformation mechanics of CNTs present in the multilayered or multitiered structures allow them to efficiently conform to the asperities of adjoining surfaces, resulting in high contact areas at the interfaces.

### 5. Properties of Thermal Interface Materials

### a. Reduction in Thermal Resistance

The CNT arrays or sheets, either as single tiered or single layered (FIG. 2A), or as multilayered or multitiered structures (FIG. 2B) formed by stacking of such CNT arrays, as described above, exhibit reduced thermal resistance. The thermal resistance can be measured using a variety of techniques known in the art, such as the photoacoustic (PA) method.

In one embodiment, the thermal resistance of the CNT arrays or sheets and the multilayered or multitiered structures formed by stacking of such CNT arrays or sheets is reduced by at least about 25%, 30%, 35%, 40%, 45%, 50%, 55%, 60%, 65%, 70% or greater compared to single tiered structures when measured, for example, using the photoacoustic method. In certain embodiments, the CNT arrays or sheets and the multilayered or multitiered structures formed by stacking of such CNT arrays or sheets exhibit thermal resistances of less than about 2.0, 1.0, 0.9, 0.8, 0.7, 0.6, 0.5, 0.4, 0.3, 0.2, or 0.1 cm² K/W. In such embodiments, the thermal resistance is about 1.0, preferably about 0.7 cm² K/W. In certain embodiments, the CNT arrays or sheets and the multilayered or multitiered structures formed by stacking of such CNT arrays or sheets exhibit thermal resistances of between about 2 and 0.1 cm² K/W. In such embodiments, the thermal resistance is about 2, 1, 0.9, 0.8, 0.7, 0.6, 0.5, 0.4, 0.3, 0.2, or 0.1 cm² K/W. In some embodiments, the thermal resistance value of a multilayered or multitiered structures formed by stacking of CNT arrays or sheets is the same or substantially unchanged as compared to the value(s) of the single layer arrays used to form the stack; “substantially,” as used herein refers to less than a 10%, 5%, 4%, 3%, 2%, or 1% change.

In some instances, the multilayered or multitiered structures formed by stacking of CNT arrays or sheets, when used, for example, as thermal interface materials (TIMs) exhibit thermal resistance hysteresis and stable operation over a wide pressure range of 0 to 500 psi, 0 to 400 psi, 0 to 300 psi, 0 to 200 psi, or 0 to 100 psi, when increasing and decreasing the pressure on the TIM in the aforementioned ranges.

In one embodiment, the apparent thermal conductivity of the CNT arrays or sheets and the multilayered or multitiered structures formed by stacking of such CNT arrays or sheets is increased by at least about 25%, 30%, 35%, 40%, 45%, 50%, 55%, 60%, 65%, 70% or greater compared to single tiered structures. In some embodiments, the CNT arrays or sheets and the multilayered or multitiered structures formed by stacking of such CNT arrays or sheets exhibit conductance values in the range of about 1-2500 W/m-K, 1-2000 W/m-K, 1-1500 W/m-K, 1-1000 W/m-K, 1-500 W/m-K, 5-500 W/m-K, 5-400 W/m-K, 5-300 W/m-K, 5-200 W/m-K, 5-150 W/m-K, 5-100 W/m·K, or 3-30 W/m-K.

A coating may be optionally applied to the CNT arrays or sheets prior to, during, or following stacking to form multilayered or multitiered structures formed by stacking of such CNT arrays or sheets. Coating(s) were shown to be an effective means for increasing the contact area and reducing the thermal resistance of CNT forest thermal interfaces. The bonding process added by inclusion of nanoscale coatings around individual CNT contacts includes, for example, pulling, through capillary action, of additional CNTs close to the interface to increase contact area.

The multilayered or multitiered structures, demonstrate good compliance, i.e., the ability to conform when contacted to one or more surfaces of material(s) (such as a die or chip). Compliant multilayered or multitiered TIMs have contact areas at interfaces between surface(s) of material(s) and the TIM, such that the compliance of the multilayered or multitiered TIMs, expressed as a percentage value, is between about 1% to 50%, 1% to 40%, 1% to 30%, 1% to 25%, 1% to 20%, or 1% to 10% of the total thickness of the TIM.

The multilayered or multitiered structures also demonstrate excellent elastic recovery properties following one or more repeated deformations, typically compressions, at varying pressures up to about 50, 100, 200, 300, 400, 500 psi, or greater. Elastic recovery of the multilayered or multitiered structures, expressed as a percentage value, following one or more compressions can be greater than about 50%, 60%, 70%, 80%, 90%, 91%, 92%, 93%, 94%, 95%, 96%, 97%, 98%, or 99%. In some instances, the multilayered or multitiered structures described also demonstrate compression set properties following one or more repeated deformations, typically compressions, at varying pressures up to about 50, 100, 200, 300, 400, 500 psi, or greater. Compression set of the multilayered or multitiered structures, expressed as a percentage value, following one or more compressions can be less than about 20%, 15%, 10%, 9%, 8%, 7%, 6%, 5%, 4%, 3%, 2%, 1%, 0.9%, 0.8%, 0.7%, 0.6%, 0.5%, 0.4%, 0.3%, 0.2%, or 0.1%.

### III. Methods for Manufacturing Heat Sinks

The heat sinks described herein can be formed according to the methods detailed herein.

In one non-limiting example, the method of preparing a heat sink includes the steps of:

(a) forming a base including a thermal interface material; and

(b) forming a plurality of polymeric protrusions on at least a surface of the base.

In another non-limiting example, the method of preparing a heat sink includes the steps of:

(a) forming a first base including a thermal interface material;

(b) forming a second base including a plurality of polymeric protrusions thereon; and

(c) attaching, adhering, or bonding the first and second bases such that the polymeric protrusions extend away from the first base.

The heat sinks formed according to the methods can have any suitable dimensions needed to cover one or more surfaces of a heat-generating device (such as a computer chip or component).

A. Base

The base of the heat sink which is formed from a thermal interface material (TIM) can be prepared by forming a TIM, as described below. In some other instances, where the base of the heat sink includes optional additional layers in addition to the TIM, the base can be prepared by forming the TIM, as described below, and adding to or modifying the TIM to include one or more additional layers (such as an adhesive layer) using known methods.

The thermal interface material (TIM) can be prepared from carbon nanotube arrays or sheets and formed from a single tiered or single layered structure (FIG. 2A) or can be from multitiered or multilayered structures (FIG. 2B), as detailed below.

### 1. Carbon Nanotube Arrays

Carbon nanotube arrays can be prepared using techniques well known in the art. In one embodiment, the arrays are prepared as described in U.S. Publication No. 2014-0015158-A1, incorporated herein by reference. This method involves the use of multilayer substrates to promote the growth of dense vertically aligned CNT arrays and provide excellent adhesion between the CNTs and metal surfaces.

The multilayer substrates contain three or more layers deposited on an inert support, such as a metal surface. Generally, the multilayer substrate contains an adhesion layer, an interface layer, and a catalytic layer, deposited on the surface of an inert support. Generally, the support is formed at least in part from a metal, such as aluminum, platinum, gold, nickel, iron, tin, lead, silver, titanium, indium, copper, or combinations thereof. In certain instances, the support is a metallic foil, such as aluminum or copper foil. The support may also be a surface of a device, such as a conventional heat sink or heat spreader used in heat exchange applications.

The adhesion layer is formed of a material that improves the adhesion of the interface layer to the support. In certain embodiments, the adhesion layer is a thin film of iron. Generally, the adhesion layer must be thick enough to remain a continuous film at the elevated temperatures used to form CNTs. The adhesion layer also generally provides resistance to oxide and carbide formation during CNT synthesis at elevated temperatures.

The interface layer is preferably formed from a metal which is oxidized under conditions of nanotube synthesis or during exposure to air after nanotube synthesis to form a suitable metal oxide. Examples of suitable materials include aluminum. Alternatively, the interface layer may be formed from a metal oxide, such as aluminum oxide or silicon oxide. Generally, the interface layer is thin enough to allow the catalytic layer and the adhesion layer to diffuse across it. In some embodiments wherein the catalytic layer and the adhesion layer have the same composition, this reduces migration of the catalyst into the interface layer, improving the lifetime of the catalyst during nanotube growth.

The catalytic layer is typically a thin film formed from a transition metal that can catalyze the formation of carbon nanotubes via chemical vapor deposition. Examples of suitable materials that can be used to form the catalytic layer include iron, nickel, cobalt, rhodium, palladium, and combinations thereof. In some embodiments, the catalytic layer is formed of iron. The catalytic layer is of appropriate thickness to form catalytic nanoparticles or aggregates under the annealing conditions used during nanotube formation.

In other embodiments, the multilayer substrate serves as catalytic surface for the growth of a CNT array. In these instances, the process of CNT growth using chemical vapor deposition alters the morphology of the multilayer substrate. Specifically, upon heating, the interface layer is converted to a metal oxide, and forms a layer or partial layer of metal oxide nanoparticles or aggregates deposited on the adhesion layer. The catalytic layer similarly forms a series of catalytic nanoparticles or aggregates deposited on the metal oxide nanoparticles or aggregates. During CNT growth, CNTs form from the catalytic nanoparticles or aggregates. The resulting CNT arrays contain CNTs anchored to an inert support via an adhesion layer, metal oxide nanoparticles or aggregates, and/or catalytic nanoparticles or aggregates.

In particular embodiments, the multilayer substrate is formed from an iron adhesion layer of about 30 nm in thickness, an aluminum or alumina interface layer of about 10 nm in thickness, and an iron catalytic layer of about 3 nm in thickness deposited on a metal surface. In this embodiment, the iron adhesion layer adheres to both the metal surface and the Al (alumina nanoparticles or aggregates after growth) or Al₂O₃ interface layer. The iron catalytic layer forms iron nanoparticles or aggregates from which CNTs grow. These iron nanoparticles or aggregates are also bound to the alumina below.

As a result, well bonded interfaces exist on both sides of the oxide interface materials. Of metal/metal oxide interfaces, the iron-alumina interface is known to be one of the strongest in terms of bonding and chemical interaction. Further, metals (e.g., the iron adhesion layer and the metal surface) tend to bond well to each other because of strong electronic coupling. As a consequence, the CNTs are strongly anchored to the metal surface.

Further, subsurface diffusion of iron from the catalytic layer during nanotube growth is reduced because the same metal is on both sides of the oxide support, which balances the concentration gradients that would normally drive diffusion. Therefore, catalyst is not depleted during growth, improving the growth rate, density, and yield of nanotubes in the array.

In some embodiments, the CNT array is formed by vertically aligning a plurality of CNTs on the multilayer substrate described above. This can be accomplished, for example, by transferring an array of CNTs to the distal ends of CNTs grown on the multilayer substrate. In some embodiments, tall CNT arrays are transferred to the distal ends of very short CNTs on the multilayer substrate. This technique improves the bond strength by increasing the surface area for bonding.

The inert support for the CNT array or sheet can be a piece of metal foil, such as aluminum foil. In these cases, CNTs are anchored to a surface of the metal foil via an adhesion layer, metal oxide nanoparticles or aggregates, and catalytic nanoparticles or aggregates. In some instances only one surface (i.e., side) of the metal foil contains an array or sheet of aligned CNTs anchored to the surface. In other cases, both surfaces (i.e., sides) of the metal foil contain an array or sheet of aligned CNTs anchored to the surface. In other embodiments, the inert support for the CNT array or sheet is a surface of a conventional metal heat sink or heat spreader. In these cases, CNTs are anchored to a surface of the heat sink or heat spreader via an adhesion layer, metal oxide nanoparticles or aggregates, and catalytic nanoparticles or aggregates. This functionalized heat sink or heat spreader may then be abutted or adhered to a heat source, such as an integrated circuit package.

### 2. Carbon Nanotube Sheets

Carbon nanotube sheets can be prepared using techniques well known in the art. In one embodiment, the sheets are prepared as described in U.S. Pat. No. 7,993,620 B2. In this embodiment, CNT agglomerates are collected into sheets in-situ inside the growth chamber on metal foil substrates. The sheets can then be densified by removing the solvent. In another embodiment, the CNT sheets are made by vacuum filtration of CNT agglomerates that are dispersed in a solvent.

### 3. Coated Nanotube Arrays and Sheets

### a. Polymer Coatings

Polymers to be coated can be dissolved in one or more solvents and spray or dip coated or chemically or electrochemically deposited onto the vertical CNT forests or arrays grown on a substrate, or on a sheet, as described above. The coating materials can also be spray coated in powder form onto the top of vertical CNT forests or arrays grown on a substrate, or on

CNT sheets as described above. The coatings includes polymers or molecules that bond to CNTs through van der Waals bonds, π-π stacking, mechanical wrapping and/or covalent bonds and bond to metal, metal oxide, or semiconductor material surfaces through van der Waals bonds, π-π stacking, and/or covalent bonds.

For spray or dip coating, coating solutions can be prepared by sonicating or stirring the coating materials for a suitable amount of time in an appropriate solvent. The solvent is typically an organic solvent or solvent and should be a solvent that is easily removed, for example by evaporation at room temperature or elevated temperature. Suitable solvents include, but are not limited to, chloroform, xylenes, hexanes, pyridine, tetrahydrofuran, ethyl acetate, and combinations thereof. The polymer can also be spray coated in dry form using powders with micron scale particle sizes, i.e., particles with diameters less than about 100, 50, 40, 20, 10 micrometers. In this embodiment, the polymer powder would need to be soaked with solvent or heated into a liquid melt to spread the powder particles into a more continuous coating after they are spray deposited.

The thickness of the coatings is generally between 1 and 1000 nm, preferably between 1 and 500 nm, more preferably between 1 and 100 nm, most preferably between 1 and 50 nm. In some embodiments, the coating thickness is less than 500, 450, 400, 350, 300, 250, 200, 150, 100, 90, 80, 70, 60, 50, 40, 30, 20 or 10 nm.

Spray coating process restricts the deposition of coating to the CNT tips and limits clumping due to capillary forces associated with the drying of the solvent. The amount of coating visible on the CNT arrays increases with the number of sprays. Alternative techniques can be used to spray coat the coating materials onto the CNT arrays including techniques more suitable for coating on a commercial scale.

In another embodiment that demonstrates a coating process, CNT sheets are dipped into coating solutions or melted coatings to coat CNTs throughout the thickness of the sheets, increasing the thermal conductivity of the sheet in the cross-plane direction by greater than 20, 30, 50, or 70%.

These coated sheets are then placed between a chip and heat sink or heat spreader with the application of solvent or heat to reflow the polymer and bond the CNT sheet between the chip and heat sink or spreader to reduce the thermal resistance between the chip and heat sink or heat spreader.

In other embodiments, the coating material can be deposited on the CNT array or sheet using deposition techniques known in the art, such as chemical deposition (e.g., chemical vapor deposition (CVD)), aerosol spray deposition, and electrochemical deposition.

In one embodiment, a polymer coating can be applied by electrochemical deposition. In electrochemical deposition, the monomer of the polymer is dissolved in electrolyte and the CNT array or sheet is used as the working electrode, which is opposite the counter electrode. A potential is applied between the working and counter electrode with respect to a third reference electrode. The monomer is electrooxidized on the CNT array tips or sheet sidewalls that face the electrolyte as a result of the applied potential. Controlling the total time in which the potential is applied controls the thickness of the deposited polymer layer.

In some embodiments, the coating material is, or contains, one or more oligomeric and/or polymeric materials. In particular embodiments, the polymer can be a conjugated polymer, including aromatic and non-aromatic conjugated polymers. Suitable classes of conjugated polymers include polyaromatic and polyheteroaromatics including, but not limited to, polythiophenes (including alkyl-substituted polythiophenes), polystyrenes, polypyrroles, polyacetylenes, polyanilines, polyfluorenes, polyphenylenes, polypyrenes, polyazulenes, polynaphthalenes, polycarbazoles, polyindoles, polyazepines, poly(3,4-ethylenedioxythiophenes), poly(p-phenyl sulfides), and poly(p-phenylene vinylene). Suitable non-aromatic polymers include, but are not limited to, polyacetylenes and polydiacetylenes. The polymer classes listed above include substituted polymers, wherein the polymer backbone is substituted with one or more functional groups, such as alkyl groups. In some embodiments, the polymer is polystyrene (PS). In other embodiments, the polymer is poly(3-hexythiophene) (P3HT).

In other embodiments, the polymer is a non-conjugated polymer. Suitable non-conjugated include, but are not limited to, polyvinyl alcohols (PVA), poly(methyl methacrylates) (PMMA), polysiloxanes, polyurethanes, polydimethylsiloxanes (PDMS), and combinations (blends) thereof.

In other embodiments, the polymer is a paraffin wax. In other embodiments, the polymer is a synthetic wax such as Fischer-Tropsch waxes or polyethylene waxes. In other embodiments, the polymer is a wax that has a melting temperature above 80, 90, 100, 110, and 120° C., preferably above 130° C.

In some other embodiments, the polymer is an adhesive, such as, but not limited to, a hot glue or hot melt adhesive that combines wax, tackifiers and a polymer base to provide improved surface adhesion. In some embodiments, the adhesive is a pressure sensitive adhesive. In certain other embodiments the adhesive is a monomer that polymerizes upon contact with air or water such as a cyanoacrylate. In yet other embodiments, the adhesive is a combination of a pressure sensitive adhesive polymer and a thermally activated (or activatable) adhesive polymer which enhances ease of adhesion of a multilayered or multitiered structure described herein which includes such a combination of coatings to a surface(s), by way of the pressure sensitive adhesive and additional and more permanent or semi-permanent adhesion by way of the thermal adhesive.

### b. Metallic Nanoparticles

The CNT arrays or sheets can be coated with one or more metal nanoparticles. One or more metal nanoparticles may be adsorbed to the distal ends and/or sidewalls of the CNTs to bond the distal ends of the CNTs to a surface, reduce thermal resistance between the CNT array or sheet and a surface, or combinations thereof. Metal nanoparticles can be applied to CNT arrays or sheets using a variety of methods known in the art. For example, a solution of metal thiolate such as palladium hexadecanethiolate can be sprayed or spin coated onto the distal ends and/or sidewalls of the CNTs, and the organics can be baked off to leave palladium nanoparticles. In another example, electron-beam or sputter deposition can be used to coat metal nanoparticles or connected “film-like” assemblies of nanoparticles onto the distal ends and/or sidewalls of the CNTs. The metallic particles can be coated simultaneously with the coating or before or after coating.

Examples of suitable metal nanoparticles include palladium, gold, silver, titanium, iron, nickel, copper, and combinations thereof.

### c. Flowable or Phase Change Materials

In certain embodiments, flowable or phase change materials can be applied to the CNT array or sheet. Flowable or phase change materials may be added to the CNT array or sheet to displace the air between CNTs and improve contact between the distal ends of CNTs and a surface, and as a result reduce thermal resistance of the array or sheet and the contact between the array or sheet and a surface, or combinations thereof. Flowable or phase change materials can be applied to CNT arrays or sheets using a variety of methods known in the art. For example, flowable or phase change materials in their liquid state can be wicked into a CNT array or sheet by placing the array or sheet in partial or full contact with the liquid.

Examples of suitable flowable or phase change materials include paraffin waxes, polyethylene waxes, hydrocarbon-based waxes in general, and blends thereof. Other examples of suitable flowable or phase change materials that are neither wax nor polymeric include liquid metals, oils, organic-inorganic and inorganic-inorganic eutectics, and blends thereof. In some embodiments, the coating material(s) and the flowable or phase change material are the same.

The coatings, metallic particles, and/or flow or phase change materials described above can be applied directly to the CNT arrays or sheets and the coated CNT arrays or sheets can subsequently be stacked to form multilayered or multitiered structures. In certain other embodiments, the coatings, metallic particles, and/or flow or phase change materials described above are applied during the stacking of two or more CNT arrays or sheets. In still other embodiments, the coatings, metallic particles, and/or flow or phase change materials described above are applied following the stacking of two or more CNT arrays or sheets. In non-limiting embodiments, multilayered or multitiered structure(s) are formed by first stacking two or more CNT arrays or sheets and then the at least partially interdigitated tiers of the formed structures are infiltrated with one or more coatings, metallic particles, and/or flow or phase change materials, or combinations thereof. The introduction of such coatings/materials into the at least partially interdigitated tiers of the multilayered or multitiered structure(s) prior to, during, or after stacking can be used to modify and/or enhance the thermal transport or thermal resistance properties of the multilayered or multitiered structures resulting from the stacking of the CNT arrays or sheets.

### 4. Multilayered or Multitiered Structures

In the embodiments described herein, the multilayered or multitiered structures formed by stacking of CNT arrays or sheets are formed by a method including the steps of:

(1) providing at least two or more CNT arrays or sheets; and

(2) stacking the at least CNT arrays or sheets

wherein the stacking results in at least partial interdigitation of the nanostructures, CNTs, of the arrays or sheets. In some embodiments, the method of making the multilayered or multitiered structures further includes a step of applying or infiltrating a coating, a coating of metallic nanoparticles, and/or a coating of flowable or phase change materials, which are described above. In some embodiments, the step of applying or infiltrating a coating, a coating of metallic nanoparticles, and/or a coating of flowable or phase change materials occurs prior to stacking, alternatively during stacking, or alternatively after stacking. In yet other embodiments, the method includes applying pressure during the stacking step. The applied pressure may be in the range of about 1-100 psi, 1-50 psi, 1-30 psi, more preferably about 1-20 psi, and most preferably about 1-15 psi. In some embodiments, the pressure is about 15 psi. Pressure may be applied continuously until the adjacent tiers are bonded, if a coating material(s) which can act as a bonding agent, such as an adhesive or phase change material, is used. Pressure may be applied for any suitable amount of time. In some embodiments, only a short time is used, such as less than 1 minute, if no bonding agent is used.

At least two CNT arrays or sheets can be stacked to form the multilayered or multitiered structures. For example, FIG. 2 shows stacking of three CNT arrays (right side). By using more CNT arrays the thickness of the multilayered or multitiered structures can be increased as needed. In some embodiments, up to 5, 10, 15, 20, 25, 30, or more CNT arrays or sheets can be stacked according to the method described above. The thickness of the resulting multilayered or multitiered structures formed by stacking can be in the range 1-10,000 microns or more.

In certain embodiments, the multilayered or multitiered structures can be formed by stacking multiple tiers of CNT arrays in a stepped manner, off-set manner, and/or other non-uniform manner in order to be able to conform to complex surfaces.

In a non-limiting embodiment, at least two vertically aligned arrays or sheets formed on supports/substrates are stacked/contacted such that the nanostructure elements, such as CNTs, of the arrays at least partially interdigitate on contact. In one embodiment full interdigitation of nanostructure elements of the arrays occurs within one another when stacked. In other embodiments the arrays may interdigitate only at the tips of the nanostructure elements, such as CNTs. In yet other embodiments, the individual nanostructures can navigate through the nanostructures of the adjacent array during the interdigitating process.

In some embodiments the nanostructures of the stacked arrays, which interdigitate at least partially, may also form into larger superstructures, such as, but not limited to, tube bundles, clumps, or rows. These superstructures may be formed through mechanisms such as capillary clumping or by way of application of a polymer coating prior to, during, or following the stacking process.

In some embodiments, a polymer coating and/or adhesive, or other coating as described above, is applied to the CNT array(s) which are then stacked. In such embodiments, the thickness of the coating and/or adhesive, or other coating as described above, is about 1-1000 nm, more preferable 1-500 nm, and most preferably 1-100 nm.

In certain embodiments of the above method, following the stacking step the method further includes a step of applying an adhesive, such as but not limited to a hot glue or hot melt adhesive that combines wax, tackifiers and a polymer base to the resulting stack to provide improved adhesion properties to one or more surfaces of the stacked/tiered CNT arrays forming the multilayered or multitiered structure. In some embodiments, the adhesive is a pressure sensitive adhesive. In yet other embodiments, the adhesive is a combination of a pressure sensitive adhesive polymer and a thermally activated (or activatable) adhesive polymer which enhances ease of adhesion of a multilayered or multitiered structure described herein which includes such a combination of coatings to a surface(s), by way of the pressure sensitive adhesive and additional and more permanent or semi-permanent adhesion by way of the thermal adhesive.

In yet other embodiments, one or more tiers of the stacked arrays described above may be substituted with other materials to afford a composite stack. Such materials include, but are not limited to, solders, greases, adhesives, phase change materials, gels, heat spreaders, compliant pads, and/or (elastomeric) gap pads. The substitution of these materials for one or more CNT array tiers of the multitiered or multilayered stacks can be used to further tune the properties of the resulting composite stack. Such composite stacks may be used for a variety of applications described below, such as thermal interface materials (TIMs).

B. Polymeric Protrusions

Following formation of a base, the polymeric protrusions are typically formed onto the base by a suitable means. The polymeric protrusions are formed on at least one side of the base. The polymeric protrusions which form pan of the heat sink article are contiguous with the base formed from a thermal interface material. The base includes a plurality of polymeric protrusions extending away from the base.

Suitable processes for forming the polymeric protrusions onto the base include, but are not limited to, molding, vacuum forming, thermoforming, compression molding, continuous molding (replication), profile extrusion (through-molding), injection molding, embossing, cold forming, additive manufacturing, or combinations thereof.

The polymeric protrusions can be made according to the processes above from any known suitable polymer, such as, but are not limited to melt processable or extrudable polymer(s). Suitable examples include but are not limited to thermoplastic polymers, elastomeric polymers, thermoset polymers, and thermoplastic elastomers. Two or more polymers may be used in combination, such as in layers and/or blends to form the polymeric protrusions. The thermoset polymers used to form the protrusions, for example, can be crosslinked via known means, such as chemical or thermal agents, catalysts, irradiation, heat, light, and combinations thereof. In some instances, the polymer(s) used to form the protrusions may be selected such that it has a glass transition temperature below about 25° C. in order for the polymer to not be completely hard and glassy at room temperature.

The polymeric protrusions may be formed from polymer(s) alone or may further contain one or more thermally conductive materials or fillers therein. Exemplary conductive materials or fillers include, but are not limited to carbon black, carbon nanotubes (including any combination of single-walled, double-walled., or multi-wailed carbon nanotubes), graphite, graphene, reduced graphene oxide, partially reduced graphene oxide, carbon fibers, carbon fibers coated with a metal or other conductive material such as nickel, ceramic fiber mesh, ceramics which includes for example: boron nitride, aluminum oxide, silicon carbide, aluminum nitride, aluminum trihydrate, magnesium hydroxide, metals such as aluminum, iron oxides, copper, stainless steel, etc., including metal foils. In some instances, the conductive materials or fillers are in the form of a plurality of particles where suitable particles can vary by size, type (such as crystal forms of hexagonal, rhombohedral, cubic, etc.), agglomerated particle size, aspect ratio, surface coatings that enhance surface physical properties of the particles, pH characteristics (e.g., acidic, basic, including Lewis acid or Lewis base particles), and particle blends. The particles may be spherical, non-spherical, or elongated particles and may be aligned along the major dimension of the polymeric protrusions. Higher aspect ratio particle shapes may also be used which include fibers, rods, needles, whiskers, ellipsoids, and flakes. The particles may be hollow, solid, or metal-coated particles. When adding conductive fillers, molding parameters may be tuned to give preferential alignment of the fillers, allowing conductivity to be maximized in the direction of heat transfer.

The polymer(s) forming each of the polymeric protrusions of the heat sink may be the same, similar, or different. Typically, each of the polymeric protrusions of a heat sink are formed of the same or of substantially similar polymer compositions. “Substantially similar” means having a composition wherein at least about 85 weight percent (wt %), more preferably at least about 90 wt %, and in some embodiments at least about 95 wt %, of the substantially similar compositions are identical. In certain instances, each of the polymeric protrusions of a heat sink are formed from dissimilar polymer compositions where “dissimilar” means that the compositions can vary by more than about 15 wt %.

Molding, for example, can be used to form polymeric protrusions having parallel sidewalls (e.g., cylindrical), tapered sidewalls, or a combination thereof, which facilitates removal from a mold used in their manufacture. In a non-limiting example, selection of a suitable mold can be used to achieve polymeric protrusions having any desired major dimension (height) and minor dimension (width) and distance between adjacent polymeric protrusions. A mold can contain a plurality of arranged cavities of a chosen size, shape, and orientation to form a plurality of polymeric protrusions onto the base or onto a protrusion base which is subsequently attached, adhered, or bonded to the base including a TIM. Cavities may be arranged, sized, and shaped as desired to form a suitable surface structures from a polymeric material or blends thereof. Cavities of a mold may be formed in any suitable manner, such as one or more of chemical, electrical, and mechanical machining or forming processes. Examples include drilling, machining, laser drilling, e-beam drilling, water jet machining, casting, etching, die punching, diamond turning, engraving knurling, and the like. The placement of the cavities determines the spacing and orientation of the polymeric protrusion on the base of the heat sink.

The mold cavities can be open at the end of the cavity opposite the surface from which molten polymeric material is applied to facilitate injection of the polymeric material into the cavities. Vacuum can be applied to the cavity so that the molten polymeric material fills substantially the entire cavity. The mold cavities may be designed to facilitate release of the polymeric structures, and thus may include angled sidewalls, or include a release coating on the cavity walls. The mold surface may also include a release coating thereon selected to facilitate release of the base layer from the mold.

Polymer(s) in a liquid state (i.e., molten) can be flowed into the mold cavities, and over the surface of the mold to form a layer of material, or a separate stream of polymeric material of the same or different composition can be used to form a layer of material. The polymeric material(s) are typically be heated to an appropriate temperature, and then filled into the cavities. This coating technique can be any conventional technique, such as calendar coating, cast coating, curtain coating, die coating, extrusion, gravure coating, knife coating, spray coating or the like. The addition of polymeric material(s) into a mold may be assisted by the application of pressure. The addition of polymeric material(s) into a mold may be assisted by evacuating the cavities of the mold before applying the polymeric material(s).

After the polymeric material(s) have been flowed into the cavities of the mold, the polymeric material(s) are cooled to solidify and form the desired topography of polymeric protrusions. In some instances, the base discussed above is placed onto the mold and the polymeric protrusions are formed directly onto the base after the polymeric material(s) are cooled and solidify. In other instances, the solidified polymeric material having the protrusions is separated from the mold and contacted, adhered, and/or bonded to the base of the heat sinks, optionally by way of an adhesive. Part or the entirety of the mold may be cooled to aid in solidifying the polymeric material(s) forming the polymeric protrusion structures on a protrusion base layer, which is subsequently contacted, adhered, and/or bonded to the base of the heat sinks, optionally by way of an adhesive. Cooling can be effected directly or indirectly via any known means such as using water, air, other heat transfer fluids, or other cooling processes.

Some molding processes may use curable or thermoset polymers, such as those already described above. When such resins are used, the resin typically is applied to the mold as a liquid in an uncured or unpolymerized and/or molten state. After the resin has been coated onto the mold, it is polymerized or cured and cooled (if necessary) until the resin is solid. Generally, the polymerization process involves either a setting time, or exposure to an energy source, or both to facilitate the polymerization. The energy source can be heat or other radiation energy such as an electron beam, ultraviolet light, or visible light. After the resin is solidified, it can be removed from the mold. In some embodiments, it may be desired to further polymerize or cure the thermosetting resin after the polymeric protrusions are removed from the mold cavities. Examples of suitable thermosetting resins include melamine resins, formaldehyde resins, acrylate resins, epoxy resins, urethane resins, silicone resins, fluoropolymer resins, and combinations thereof.

Without limitation, molds can be made from suitable materials that range from rigid to flexible. The mold components can be made of metal, ceramic, polymeric materials, or combinations thereof. The materials forming the mold must have sufficient integrity and durability to withstand the thermal energy associated with the particular flowable polymeric material used to form the polymeric protrusions and any surface features desired.

In other instances, other methods may be used to form the plurality of polymeric protrusions of the heat sink including, but not limited to vacuum forming, thermoforming, compression molding, continuous molding (replication), profile extrusion (through-molding), injection molding, embossing, cold forming, or combinations thereof can be used to achieve polymeric protrusions having a desired major dimension (height) and minor dimension (width) and distance between adjacent polymeric protrusions.

In many instances, the polymeric protrusions are formed directly onto the base. The polymeric protrusions can be attached to the base via molding where the base is contacted with a mold having cavities that are filled with polymeric material(s), as described above. Other suitable means for forming the polymeric protrusion directly on the base include additive manufacturing, melt bonding, solvent bonding, etc. In some instances, the polymeric protrusions may be formed separately onto its own protrusion base layer (formed from the same or different polymer(s) as the protrusions) which is then attached, adhered, or otherwise bonded to the base layer. Attaching, adhering, or bonding separate base and polymeric protrusion components may be achieved with or without the application of pressure. Optionally, an adhesive may be used to achieve the attachment or bonding of the base and polymeric protrusion components to provide the heat sink. Suitable adhesives are described throughout this disclosure.

### IV. Heat Sink Applications

The heat sinks include a base having a single layered or single tiered or a multilayered or multitiered carbon nanotube-based thermal interface material (TIM). The heat sinks can be flexible and conformable.

Accordingly, such heat sinks are well suited for applications where the heat sink can conform to heat-generating devices or sources, such as computer chips, computer modules, multi-component system, electronic devices (i.e., displays), etc. The heat sink may be attached to sources of waste heat such as hot pipes for temperature control or energy extraction. The heat sink can be abutted or adhered to the heat generating device or source to improve the transfer of heat from the heat generating device or source. The heat sinks are well suited for fitting into complex and/or volume constrained devices, sources, components, or packages.

The flexible and conformable heat sinks allow for intimate contact between surface(s) of heat generating devices or sources, as the surfaces may be curved, bent, bowed, or be otherwise deformed by design or due to thermal expansion(s) of the devices or sources.

The heat sinks can be applied to node multi-chip modules (MCMs). The flexible and conformable heat sinks allow for uniform or essentially uniform contact with MCMs. In certain instances, it can be difficult to predict or model warpage which may occur in individual chips, circuits, or MCMs during operation at normal temperatures. Warpage can lead to defects and even to failure in certain instances. Accordingly, the heat sinks are particularly suitable for such applications because they can be readily adjusted/reformed, if needed, to meet the tolerances required for such applications. As microchips heat up, they can warp leading to a center to-edge warpage greater than 50 μm whereas in multichip applications, the heat sinks here can accommodate chip-to-chip offsets of 100 μm or more and/or can also accommodate chip center-to-edge warpages of greater than 50 μm.

The heat sinks can be used with personal computers and components thereof, server computers and components thereof, memory modules, graphics chips, radar and radio-frequency (RF) devices, disc drives, displays, including light-emitting diode (LED) displays, lighting systems, pipes, automotive control units, power-electronics, solar cells, batteries, communications equipment, such as cellular phones, thermoelectric generators, and imaging equipment, including MRIs. The heat sinks act as efficient heat spreaders when a sufficient number of tiers (i.e. 1, 2, 3, 4, 5, or more tiers) are present in the TIM and provide an in-plane thermal conductivity which is on par with that of the base material of the substrate, which is typically a metal.

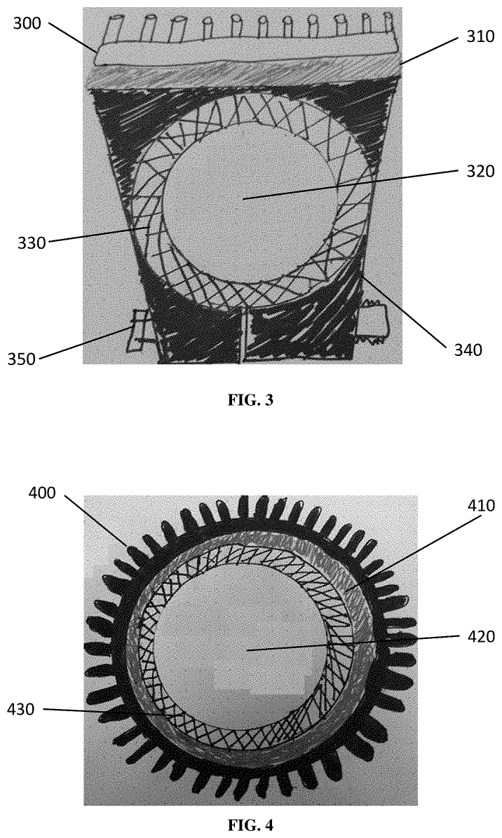

In some instances, the heat sinks are contacted to a thermoelectric generator in contact with a waste heat source, as shown in FIGS. 3 and 4. For example, as shown in detail on FIG. 3, the heat sink can be placed on a thermoelectric generator on a saddle (made of out of metal, for example) where the saddle is wrapped around a waste heat source, such as a pipe, and the heat source is, as one example, steam. In another example, as shown in detail on FIG. 4, the thermoelectric generator is flexible is wrapped around a waste heat source, such as a pipe, and the heat source is, as one example, steam. As shown in FIG. 4, a heat sink as described herein which is flexible may be wrapped around the thermoelectric generator. In both non-limiting illustrations shown in FIGS. 3 and 4, the placement of a heat sink can maximize the difference in temperature between hot and cold sides of the thermoelectric generator in order to increase its efficiency. In both non-limiting illustrations shown in FIGS. 3 and 4, ambient air (not shown), for example, can be circulate or be circulated around the heat sinks.

In certain embodiments, the multilayered or multitiered structures of the TIM in the base layer of the heat sink can be formed by stacking multiple tiers of CNT arrays in a stepped manner, off-set manner, and/or other non-uniform manner in order to more readily conform to complex surfaces, such as those of MCMs, which are typically non-uniform. In such instances, customized multilayered or multitiered structures may be designed and formed by stacking two or more CNT array tiers in a manner that conforms to the complex surface of a given heat-generating device or source.

In certain embodiments, the heat sinks may be used at temperatures which are above ambient temperature, at ambient temperature, below ambient temperature, below freezing, or at cryogenic temperatures.

The heat sinks can also be used for electromagnetic and/or radio frequency shielding.

Unless defined otherwise, all technical and scientific terms used herein have the same meanings as commonly understood by one of skill in the art to which the disclosed invention belongs. Publications cited herein and the materials for which they are cited are specifically incorporated by reference.

Those skilled in the art will recognize, or be able to ascertain using no more than routine experimentation, many equivalents to the specific embodiments of the invention described herein. Such equivalents are intended to be encompassed by the following claims.

We claim:

1. A flexible heat sink comprising:
a plurality of polymeric protrusions extending away from a base, each protrusion having a major dimension and a minor dimension;
wherein the plurality of polymeric protrusions are contiguous with the base which comprises a thermal interface material; and
wherein the thermal interface material comprises at least a first layer or tier comprising a carbon nanotube array or sheet.

2. The flexible heat sink of claim 1, wherein the plurality of polymeric protrusions are each independently vertical or substantially vertical posts, cones, or extended rows or rails, or combinations thereof.

3. The flexible heat sink of claim 1, wherein the plurality of polymeric protrusions have different heights or shapes or have the same heights or shapes.

4. The flexible heat sink of claim 1, wherein the plurality of polymeric protrusions are formed from melt processable or extrudable polymer.

5. The flexible heat sink of claim 1, wherein the plurality of polymeric protrusions are formed from thermoplastic polymers, elastomeric polymers, thermoset polymers, thermoplastic elastomers, and combinations thereof.

6. The flexible heat sink of claim 1, wherein the plurality of polymeric protrusions further comprise one or more thermally conductive materials or fillers.

7. The flexible heat sink of claim 1, wherein the plurality of polymeric protrusions each have parallel sidewalls (e.g., cylindrical), tapered sidewalls, or a combination thereof.

8. The flexible heat sink of claim 1, wherein the plurality of polymeric protrusions are flexible.

9. The flexible heat sink of claim 1, wherein the base is flexible and conformable.

10. The flexible heat sink of claim 1, wherein the base has a uniform thickness.

11. The flexible heat sink of claim 1, wherein the base has a non-uniform thickness.

12. The flexible heat sink of claim 1, wherein the base is corrugated, textured, contoured, or a combination thereof.

13. The flexible heat sink of claim 1, wherein the base includes one or more additional layers thereon preferably opposite the surface having thereon the polymeric protrusions.

14. The flexible heat sink of claim 13, wherein the one or more additional layers are selected from a backing layer, an adhesive layer, a reinforcing layer, a heat spreading layer, or a combination thereof.

15. The flexible heat sink of claim 1, wherein the base is conformable.

16. The flexible heat sink of claim 15, wherein the base has a compliance of about 5 to 50% of the thickness of the base.

17. The flexible heat sink of claim 1, further comprising a coating material on at least some of the interstitial space between the carbon nanotubes of the carbon nanotube array or sheet.

18. The flexible heat sink of claim 1, wherein the carbon nanotube array or sheet is on a metal substrate.

19. The flexible heat sink of claim 1, wherein the thermal interface material further comprises at least a second layer or tier comprising a carbon nanotube array or sheet,
wherein the carbon nanotubes of the array or sheet of the first layer or tier at least partially interdigitate the carbon nanotubes of the array or sheet of the second layer or tier to form a multilayered or multitiered structure.

20. The flexible heat sink of claim 19, wherein the carbon nanotube array or sheet of the second layer or tier is on a metal substrate.

21. The flexible heat sink of claim 19, further comprising three, four, five, six, or seven additional layers or tiers as part of the multilayered or multitiered structure.

22. The flexible heat sink of claim 19, wherein at least some of the interstitial space between the carbon nanotubes, the surfaces of the carbon nanotubes, or both of the first and second array forming the multilayered or multitiered structure is infiltrated with a coating material which is solidified within the carbon nanotube arrays or sheets.

23. The flexible heat sink of claim 17, wherein the coating material reduces the resistance to energy transport between the adjacent nanostructures, carbon nanotubes, of the carbon nanotube arrays or sheets present.

24. The flexible heat sink of claim 22, wherein the coating material reduces the resistance to energy transport between the adjacent nanostructures, carbon nanotubes, of the carbon nanotube arrays or sheets present.

25. The flexible heat sink of claim 23, wherein the coating material is selected from the group consisting of an adhesive, a phase change material, or a combination thereof.

26. The flexible heat sink of claim 25, wherein the coating material is selected from the group consisting of an adhesive, a phase change material, or a combination thereof.

27. The flexible heat sink of claim 1, wherein the heat sink, the base, or the thermal interface material has a thermal resistance of about 0.1 to 2.1 cm²-K/W.

28. The flexible heat sink of claim 1, wherein the thermal interface material is conformable.

29. The flexible heat sink of claim 28, wherein the thermal interface material has a compliance of about 5 to 50% of the thickness of the thermal interface material.

30. The flexible heat sink of claim 1, wherein the thermal interface material is adhesive or comprises an adhesive.

31. The flexible heat sink of claim 30, wherein the adhesive is a pressure sensitive adhesive.

32. The flexible heat sink of claim 30, wherein the adhesive comprises a combination of a pressure sensitive adhesive and a thermally activatable adhesive.

33. The flexible heat sink of claim 30, wherein the adhesive comprises a thermoset adhesive or heat cure epoxy.

34. The flexible heat sink of claim 1, wherein the thermal interface material absorbs or reduces interference at electromagnetic and/or radio frequencies.

35. The flexible heat sink of claim 1, wherein the heat sink absorbs or reduces interference at electromagnetic and/or radio frequencies.

36. The flexible heat sink of claim 1, wherein the heat sink can conform to flat, non-flat undulating, or other uniform or non-uniform surface shapes.

37. The flexible heat sink of claim 1, wherein the heat sink is reformable and can be heated and reformed into a new shape.

38. A method of making a heat sink according to claim 1, the method comprising the steps of:
(a) forming a base comprising a thermal interface material; and
(b) forming a plurality of polymeric protrusions on at least a surface of the base;
wherein the thermal interface material comprises at least a first layer or tier comprising a carbon nanotube array or sheet.

39. A method of making a heat sink according to claim 1, the method comprising the steps of:
(a) forming a first base comprising a thermal interface material;
(b) forming a second base comprising a plurality of polymeric protrusions thereon; and
(c) attaching, adhering, or bonding the first and second bases, such that the polymeric protrusions extend away from the first base;
wherein the thermal interface material comprises at least a first layer or tier comprising a carbon nanotube array or sheet.

40. The method of claim 38, wherein the thermal interface material further comprises at least a second layer or tier comprising a carbon nanotube array or sheet,
wherein the carbon nanotubes of the array or sheet of the first layer or tier at least partially interdigitate the carbon nanotubes of the array or sheet of the second layer or tier to form a multilayered or multitiered structure.

41. The method of claim 40, wherein at least some of the interstitial space between the carbon nanotubes, the surfaces of the carbon nanotubes, or both of the first and second array forming the multilayered der multitiered structure is infiltrated with a coating material which is solidified within the carbon nanotube arrays or sheets.

42. The method of claim 41, wherein the coating material reduces the resistance to energy transport between the adjacent nanostructures, carbon nanotubes, of the carbon nanotube arrays or sheets present.

43. The method of claim 42, wherein the coating material is selected from the group consisting of an adhesive, a phase change material, or a combination thereof.

44. The method claim 38, wherein the thermal interface material is adhesive or comprises an adhesive.

45. The method of claim 44, wherein the adhesive is a pressure sensitive adhesive.

46. The method of claim 44, wherein the adhesive comprises a combination of a pressure sensitive adhesive and a thermally activatable adhesive.

47. The method of claim 44, wherein the adhesive comprises a thermoset adhesive or heat cure epoxy.

48. The method of claim 38, wherein the plurality of polymeric protrusions are each independently vertical or substantially vertical posts, cones, or extended rows or rails, or combinations thereof.

49. The method of claim 38, wherein the plurality of polymeric protrusions have different heights or shapes or have the same heights or shapes.

50. The method of claim 38, wherein the plurality of polymeric protrusions are formed from melt processable or extrudable polymer.

51. The method of claim 38, wherein the plurality of polymeric protrusions are formed from thermoplastic polymers, elastomeric polymers, thermoset polymers, thermoplastic elastomers, and combinations thereof.

52. The method of claim 38, wherein the plurality of polymeric protrusions further comprise one or more thermally conductive materials or fillers.

53. The method of claim 38, wherein the base includes one or more additional layers thereon preferably opposite the surface having thereon the polymeric protrusions.

54. The method of claim 39, wherein the first base includes one or more additional layers thereon preferably opposite the surface having thereon the polymeric protrusions.

55. The method of claim 53, wherein the one or more additional layers are selected from a backing layer, an adhesive layer, a reinforcing layer, a heat spreading layer, or a combination thereof.

56. The method of claim 54, wherein the one or more additional layers are selected from a backing layer, an adhesive layer, a reinforcing layer, a heat spreading layer, or a combination thereof.

57. A device comprising the flexible heat sink of claim 1, wherein the flexible heat sink conforms to one or more surfaces of the device which may be non-flat surfaces.

58. The device of claim 57, wherein the device is a heat-generating device or a component thereof.

59. The device of claim 58, wherein the heat-generating device or component thereof is a computer chip, computer module, a multi-component system, memory module, graphics chip, radar and radio-frequency (RF) device, disc drive, display, light-emitting diode (LED) display, lighting device, pipe, automotive control unit, solar cell, battery, communications device, thermoelectric generator, or an imaging device.
